(19) United States
(12) Patent Application Publication
(10) Pub. No.: US 2008/0251791 A1
(43) Pub. Date: Oct. 16, 2008

(54) Thin film transistor substrate and method for fabricating same

(75) Inventors: Guan-Hua Yeh, Miao-Li (TW); Hong-Gi Wu, Miao-Li (TW); Jung-Lung Huang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/082,653

(22) Filed: Apr. 14, 2008

(30) Foreign Application Priority Data
Apr. 13, 2007 (CN) 200710074014.8

(51) Int. Cl. H01L 33/00

(52) U.S. Cl. 257/71; 438/30; 257/E33.053

(57) ABSTRACT

An exemplary thin film transistor substrate (200) includes a base (201), a semiconductor pattern (202) formed on the base, a first gate insulating layer (203) formed on the semiconductor pattern, and a gate electrode (223) and a common capacitor electrode (245) formed on the first gate insulating layer. The semiconductor pattern includes a heavily doped polysilicon pattern (212) and a lightly doped polysilicon pattern (213). The gate electrode and the common capacitor electrode correspond to the lightly doped polysilicon pattern. An exemplary method for fabricating the thin film transistor substrate is also provided.

### FIELD OF THE INVENTION

The present invention relates to a thin film transistor (TFT) substrate and a method for fabricating the TFT substrate.

### GENERAL BACKGROUND

A typical LCD device is capable of displaying a clear and sharp image through thousands or even millions of pixels that make up the complete image. The LCD device has thus been applied to various electronic equipment in which messages or pictures need to be displayed, such as mobile phones and notebook computers. A liquid crystal panel is a major component of the LCD device, and generally includes a TFT substrate, a color filter substrate parallel to the TFT substrate, and a liquid crystal layer sandwiched between the two substrates.

Referring to FIG. 16, part of a typical TFT substrate is shown. The TFT substrate 100 includes a glass base 101, a semiconductor pattern 102, a first gate insulating layer 105, a gate electrode 106, a capacitor electrode 107, a second gate insulating layer 108, a gate contact portioncontact portion 111, a drain electrode 103, a source electrode 104, a passivation layer 109, and a transparent contact pattern 110. The semiconductor pattern 102 is formed on the glass base 101. The first gate insulating layer 105 is formed on the semiconductor pattern 102 and the glass base 101. The gate electrode 106 and the capacitor electrode 107 are formed on the first gate insulating layer 105. The second gate insulating layer 108 is formed on the gate electrode 106, the capacitor electrode 107, and the first gate insulating layer 105. The drain electrode 103, the source electrode 104, and the gate contact portioncontact portion 111 are formed on the second gate insulating layer 108. The passivation layer 109 is formed on the drain electrode 103, the source electrode 104, the gate contact portioncontact portion 111, and the second gate insulating layer 108. The transparent contact pattern 110 is formed on the passivation layer 109.

The drain electrode 103 and the source electrode 104 are connected to the semiconductor pattern 102 via two contact holes (not labeled) in the first and second gate insulating layers 105, 108, respectively. The gate contact portioncontact portion 111 is connected to the gate electrode 106 via a contact hole (not labeled) in the second gate insulating layer 108. The semiconductor pattern 102 includes a heavily doped polysilicon pattern 112 and a lightly doped polysilicon pattern 122. The lightly doped polysilicon pattern 122 corresponds to the gate electrode 106. The heavily doped polysilicon pattern 112 corresponds to the drain electrode 103, the source electrode 104, and the capacitor electrode 107. The transparent contact pattern 110 is connected to the drain electrode 103 via a contact hole (not labeled) in the passivation layer 109.

Referring also to FIG. 17, a flowchart summarizing a typical method for fabricating the TFT substrate 100 is shown. The method includes the following steps: step S10, forming a polysilicon layer; step S11, forming a polysilicon pattern; step S12, forming a P-type semiconductor pattern; step S13, forming a semiconductor pattern; step S14, forming a first gate insulating layer; step S15, forming a gate electrode and a capacitor electrode; step S16, forming a second gate insulating layer and contact holes; step S17, forming a source electrode, a drain electrode, and a gate contact portioncontact portion; step S18, forming a passivation layer and contact holes; and step S19, forming a transparent contact pattern.

In step S10, a polysilicon layer is formed. The glass base 101 is provided, and an amorphous silicon layer is formed on the glass base 101. Then the polysilicon layer is formed from the amorphous silicon layer by an excimer laser annealing (ELA) process.

In step S11, a polysilicon pattern is formed. A first photo-resist layer is formed on the polysilicon layer. A first photo-mask is provided to expose and develop the first photo-resist layer, so as to form a first photo-resist pattern. Then the polysilicon pattern is formed by etching the polysilicon layer. The first photo-resist pattern is removed.

In step S12, a P-type semiconductor pattern is formed. The P-type semiconductor pattern is formed by doping trivalent ions in the polysilicon pattern.

In step S13, the semiconductor pattern 102 is formed. A second photo-resist layer is formed on the P-type semiconductor pattern and the glass base 101. A second photo-mask is provided to expose and develop the second photo-resist layer, so as to form a second photo-resist pattern. Quinquevalent ions are doped in the P-type semiconductor pattern. Then part of the P-type semiconductor pattern shaded by the second photo-mask forms the lightly doped polysilicon pattern 122, and part of the P-type semiconductor pattern not shaded by the second photo-mask forms the heavily doped polysilicon pattern 112. The second photo-resist pattern is removed. The heavily doped polysilicon pattern 112 and the lightly doped polysilicon pattern 122 cooperatively constitute the semiconductor pattern 102.

In step S14, the first gate insulating layer 105 is formed. The first gate insulating layer 105 is formed on the semiconductor pattern 102 and the glass base 101.

In step S15, the gate electrode 106 and the capacitor electrode 107 are formed. A first metal layer and a third photo-resist layer are formed on the first gate insulating layer 105. A third photo-mask is provided to expose and develop the third photo-resist layer, so as to form a third photo-resist pattern. Then the gate electrode 106 and the capacitor electrode 107 are formed by etching the first metal layer. The third photo-resist pattern is removed.

In step S16, the second gate insulating layer 108 and the contact holes are formed. The second gate insulating layer 108 and a fourth photo-resist layer are formed on the gate electrode 106, the capacitor electrode 107, and the first gate insulating layer 105. A fourth photo-mask is provided to expose and develop the fourth photo-resist layer, so as to form a fourth photo-resist pattern. Then the contact holes are formed by etching the first and second gate insulating layers 105, 108. The fourth photo-resist pattern is removed.

In step S17, the source electrode 103, the drain electrode 104, and the gate contact portioncontact portion 111 are formed. A second metal layer and a fifth photo-resist layer are formed on the second gate insulating layer 108. The second metal layer is connected to the heavily doped polysilicon pattern 112 and the gate electrode 106 via the contact holes. A fifth photo-mask is provided to expose and develop the fifth photo-resist layer, so as to form a fifth photo-resist pattern. Then the source electrode 103, the drain electrode 104, and the gate contact portion 111 are formed by etching the second metal layer. The fifth photo-resist pattern is removed.

In step S18, the passivation layer 109 and contact holes are formed. The passivation layer 109 and a sixth photo-resist layer are formed on the drain electrode 103, the source electrode 104, the gate contact portion 111, and the second gate insulating layer 108. A sixth photo-mask is provided to expose and develop the sixth photo-resist layer, so as to form a sixth photo-resist pattern. Then the contact holes are formed by etching the passivation layer 109. The sixth photo-resist pattern is removed.

In step S19, the transparent contact pattern 110 is formed. A transparent conducting layer and a seventh photo-resist layer are formed on the passivation layer 109, and the transparent conducting layer is connected to the drain electrode 103 via the contact hole in the passivation layer 109. A seventh photo-mask is provided to expose and develop the seventh photo-resist layer, so as to form a seventh photo-resist pattern. Then the transparent contact pattern 110 is formed by etching the transparent conducting layer. The seventh photo-resist pattern is removed.

The method includes the above-described seven photo-mask processes, each of which is rather complicated and costly. Thus, the method for fabricating the TFT substrate 100 is correspondingly complicated and costly.

What is needed, therefore, is a TFT substrate that can overcome the above-described problems. What is also needed is a method for fabricating a TFT substrate that can overcome the above-described problems.

### SUMMARY

In one aspect, an exemplary thin film transistor substrate includes a base, a semiconductor pattern formed on the base, a first gate insulating layer formed on the semiconductor pattern, and a gate electrode and a common capacitor electrode formed on the first gate insulating layer. The semiconductor pattern includes a heavily doped polysilicon pattern and a lightly doped polysilicon pattern. The gate electrode and the common capacitor electrode correspond to the lightly doped polysilicon pattern.

In another aspect, an exemplary method for fabricating a thin film transistor substrate includes the steps: providing a base; forming a polysilicon pattern on the base in a first photo-mask process; forming a first gate insulating layer on the polysilicon pattern; forming a gate electrode and a common capacitor electrode on the first gate insulating layer in a second photo-mask process; and forming a heavily doped polysilicon pattern and a lightly doped polysilicon pattern by doping the polysilicon pattern using the gate electrode and the common capacitor electrode as a mask. The gate electrode and the common capacitor electrode correspond to the lightly doped polysilicon pattern.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is a top plan view of a pixel region of a TFT substrate according to an exemplary embodiment of the present invention, the pixel region including a storage capacitor.

FIG. 2 is an abbreviated, side cross-sectional view of part of the pixel region of FIG. 1, corresponding to line II-II thereof.

FIG. 3 is a diagram indicating a relationship of voltage and capacitance of the storage capacitor of the TFT substrate of FIG. 1.

FIG. 4 is another diagram indicating a relationship of voltage and capacitance of the storage capacitor of the TFT substrate of FIG. 1.

FIG. 5 is a flowchart summarizing an exemplary method for fabricating the pixel region of the TFT substrate of FIG. 1.

FIG. 6 to FIG. 15 are side cross-sectional views of successive precursors of the pixel region of FIG. 2, each view relating to a corresponding one of steps of the method of FIG. 5.

FIG. 16 is a side cross-sectional view of part of a conventional TFT substrate.

FIG. 17 is a flowchart summarizing a conventional method for fabricating the part of the TFT substrate of FIG. 16.

### DETAILED DESCRIPTION OF PREFERRED EMBODIMENTS

Reference will now be made to the drawings to describe preferred and exemplary embodiments of the present invention in detail.

Referring to FIG. 1, a schematic, top plan view of a pixel region of a TFT substrate according to an exemplary embodiment of the present invention is shown. The TFT substrate 200 includes a plurality of gate lines 210 that are parallel to each other and that each extend along a first direction, and a plurality of data lines 220 that are parallel to each other and that each extend along a second direction orthogonal to the first direction. The smallest rectangular area formed by any two adjacent gate lines 210 together with any two adjacent data lines 220 defines a pixel region 290 thereat.

In each pixel region 290, a TFT 230 is provided in the vicinity of a respective point of intersection of one of the gate lines 210 and one of the data lines 220. The TFT 230 includes a gate electrode 223, a source electrode 227, and a drain electrode 228. The gate electrode 223 is connected to the gate line 210, and the source electrode 227 is connected to the date line 220. A pixel electrode 250 is connected to the drain electrode 228. A storage capacitor 240 is disposed on the other gate line 210. The storage capacitor 240 includes a first capacitor (not labeled), and a second capacitor (not labeled) connected parallel to the first capacitor. The first capacitor includes a first electrode 243, and the second capacitor includes a second electrode (not shown). A common capacitor electrode 245 and the first electrode 243 form two electrodes of the first capacitor, and the common capacitor electrode 245 and the second electrode form two electrodes of the second capacitor. The first electrode 243 is connected to the second electrode. The first electrode 243 is connected to the pixel electrode 250. The second electrode is a lightly doped polycilicon film. The common capacitor electrode 245 extends from the gate line 210.

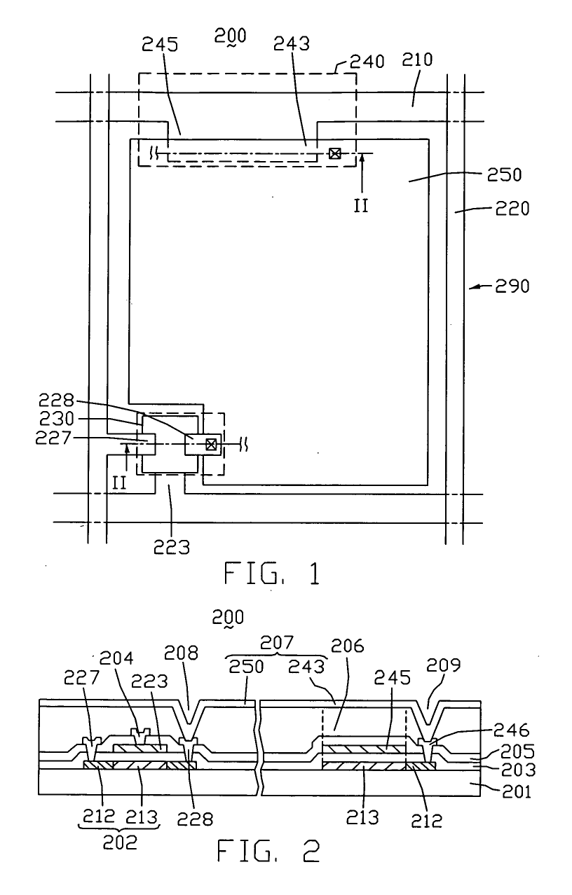

Referring to FIG. 2, a schematic, abbreviated, side cross-sectional view of part of the pixel region of the TFT substrate 200 is shown. The TFT substrate 200 further includes a base 201, a semiconductor pattern 202, a capacitor contact portion 246, a first gate insulating layer 203, a gate contact portion 204, a second gate insulating layer 205, a passivation layer 206, a transparent contact pattern 207, a first contact hole 208, a second contact hole 209, a source contact hole (not labeled), a drain contact hole (not labeled), a gate contact hole (not labeled), and a capacitor contact hole (not labeled).

The semiconductor pattern 202 is formed on the base 201. The first gate insulating layer 203 is formed on the semiconductor pattern 202 and the base 201. The gate electrode 223 and the common capacitor electrode 245 are formed on the first gate insulating layer 203. The second gate insulating layer 205 is formed on the gate electrode 223, the common capacitor electrode 245, and the first gate insulating layer 203. The drain electrode 228, the source electrode 227, the gate contact portion 204, and the capacitor contact portion 246 are formed on the second gate insulating layer 205. The source electrode 227, the drain electrode 228, and the capacitor contact portion 246 are connected to the semiconductor pattern 202 via the source contact hole, the drain contact hole, and the capacitor contact hole, respectively. The gate contact portion 204 is connected to the gate electrode 223 via the gate contact hole. The passivation layer 206 is formed on the drain electrode 228, the source electrode 227, the gate contact portion 204, the capacitor contact portion 246, and the second gate insulating layer 205. The transparent contact pattern 207 is formed on the passivation layer 206.

The semiconductor pattern 202 includes a heavily doped polysilicon pattern 212 and a lightly doped polysilicon pattern 213. The gate electrode 223 and the common capacitor electrode 245 correspond to the lightly doped polysilicon pattern 213. The drain electrode 228, the source electrode 227, and the capacitor contact portion 246 are connected to the heavily doped polysilicon pattern 212. The second electrode of the second capacitor of the storage capacitor 240 is part of the lightly doped polysilicon pattern 213 corresponding to the common capacitor electrode 245. The transparent contact pattern 207 includes the first electrode 243 and the pixel electrode 250. The pixel electrode 250 is connected to the drain electrode 228 via the first contact hole 208 in the passivation layer 206. The first electrode 243 is connected to the capacitor contact portion 246 via a second contact hole 209 in the passivation layer 206.

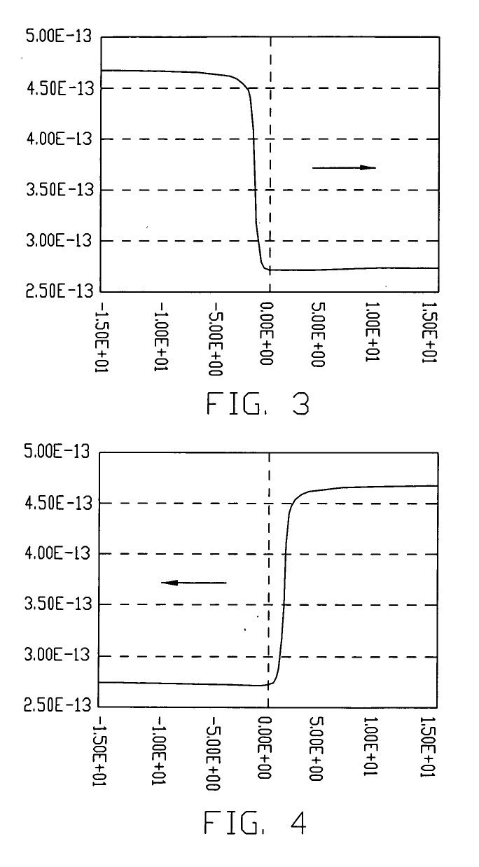

FIG. 3 is a diagram indicating a relationship of voltage and capacitance of the storage capacitor 240 when the heavily doped polysilicon pattern 212 is a P-type semiconductor and the lightly doped polysilicon pattern 213 is an N-type semiconductor. The horizontal axis of FIG. 3 represents voltage applied to the common capacitor electrode 245, and the vertical axis of FIG. 3 represents capacitance of the storage capacitor 240. FIG. 4 is a diagram indicating a relationship of voltage and capacitance of the storage capacitor 240 when the heavily doped polysilicon pattern 212 is an N-type semiconductor and the lightly doped polysilicon pattern 213 is a P-type semiconductor. The horizontal axis of FIG. 4 represents voltage applied to the common capacitor electrode 245, and vertical axis of FIG. 4 represents capacitance of the storage capacitor 240.

Referring to FIG. 3, when the voltage applied to the common capacitor electrode 245 is less than a critical voltage, the capacitance of the storage capacitor 240 is generally constant. Because the heavily doped polysilicon pattern 212 is a P-type semiconductor and the lightly doped polysilicon pattern 213 is an N-type semiconductor, the TFT 230 is a PNP-type TFT. In this case, when the gate voltage of the TFT 230 is a negative voltage, the TFT 230 is switched on. The common capacitor electrode 245 extends from the gate line 210. Because the gate voltage is less than the critical voltage, the voltage applied to the common capacitor electrode 245 is less than the critical voltage. Thus, the capacitance of the storage capacitor 240 remains constant.

Referring to FIG. 4, when the voltage applied to the common capacitor electrode 245 is greater than a critical voltage, the capacitance of the storage capacitor 240 is generally constant. Because the heavily doped polysilicon pattern 212 is an N-type semiconductor and the lightly doped polysilicon pattern 213 is a P-type semiconductor, the TFT 230 is an NPN-type TFT. In this case, when the gate voltage of the TFT 230 is a positive voltage, the TFT 230 is switched on. The common capacitor electrode 245 extends from the gate line 210. Because the gate voltage is greater than the critical voltage, the voltage applied to the common capacitor electrode 245 is greater than the critical voltage. Thus, the capacitance of the storage capacitor 240 remains constant.

Part of the lightly doped polysilicon pattern 213 is used as the second electrode of the second capacitor of the storage capacitor 240. Therefore whether the heavily doped polysilicon pattern 212 is a P-type semiconductor and the lightly doped polysilicon pattern 213 is an N-type semiconductor, or whether the heavily doped polysilicon pattern 212 is an N-type semiconductor and the lightly doped polysilicon pattern 213 is a P-type semiconductor, the capacitance of the storage capacitor 240 remains constant, and the second capacitor of storage capacitor 240 can work effectively.

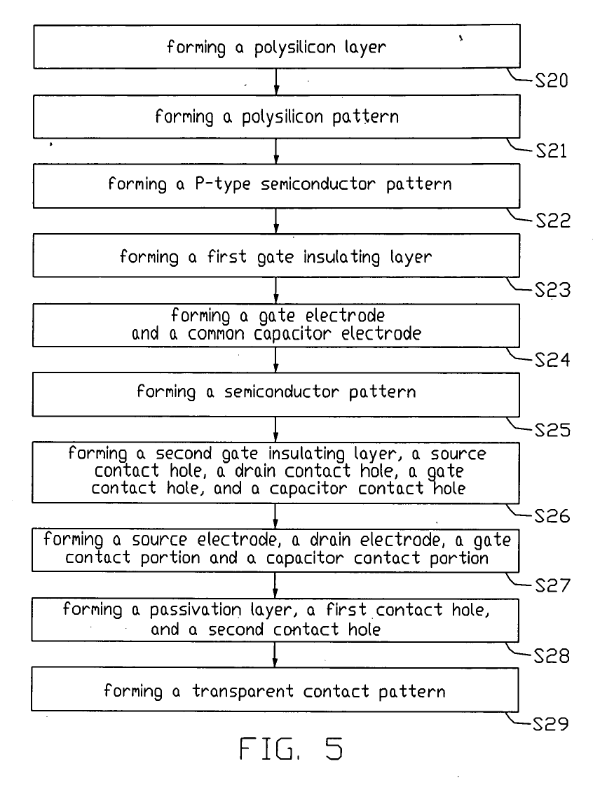

Referring to FIG. 5, a flowchart summarizing an exemplary method for fabricating the TFT substrate 200 is shown. The method includes the following steps: step S20, forming a polysilicon layer; step S21, forming a polysilicon pattern; step S22, forming a P-type semiconductor pattern; step S23, forming a first gate insulating layer; step S24, forming a gate electrode and a common capacitor electrode; step S25, forming a semiconductor pattern; step S26, forming a second gate insulating layer, a source contact hole, a drain contact hole, a gate contact hole, and a capacitor contact hole; step S27, forming a source electrode, a drain electrode, a gate contact portion, and a capacitor contact portion; step S28, forming a passivation layer, a first contact hole, and a second contact hole; and step S29, forming a transparent contact pattern.

In step S20, a polysilicon layer 302 is formed. Referring also to FIG. 6, the base 201 is provided, and an amorphous silicon layer is formed on the base 201. Then the polysilicon layer 302 is formed from the amorphous silicon layer by an ELA process.

In step S21, a polysilicon pattern 303 is formed. Referring also to FIG. 7, a first photo-resist layer is formed on the polysilicon layer 302. A first photo-mask is provided to expose and develop the first photo-resist layer, so as to form a first photo-resist pattern. Then the polysilicon pattern 303 is formed by etching the polysilicon layer. The first photo-resist pattern is removed.

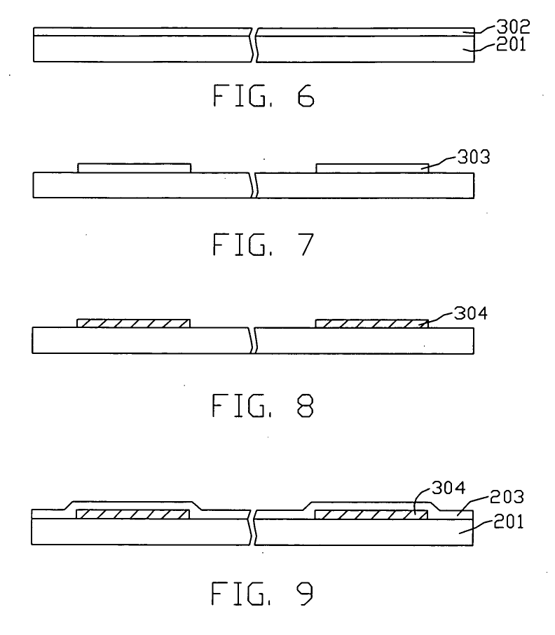

In step S22, a P-type semiconductor pattern 304 is formed. Referring also to FIG. 8, the P-type semiconductor pattern 304 is formed by doping trivalent ions in the polysilicon pattern 303.

In step S23, the first gate insulating layer 203 is formed. Referring also to FIG. 9, the first gate insulating layer 203 is formed by depositing a first silicon oxide (SiOₓ) layer on the P-type semiconductor pattern 304 and the base 201. The form of first monox can for example be SiO_{y,}, SiO_{z,}, etc.

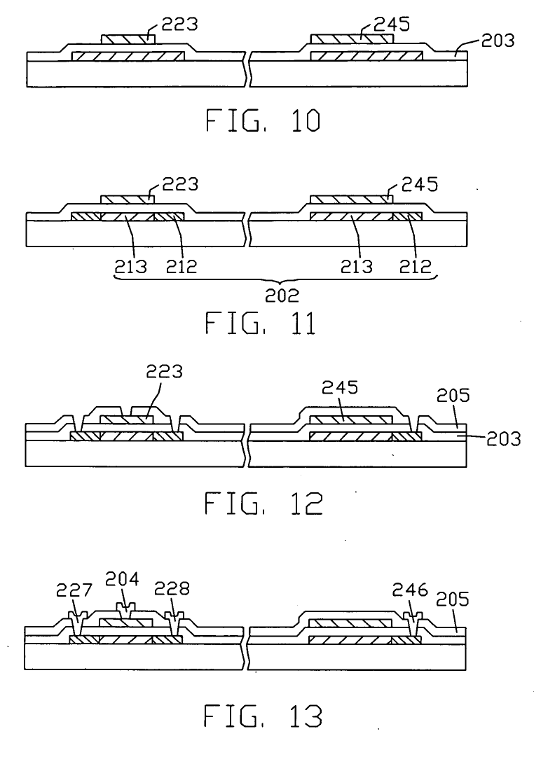

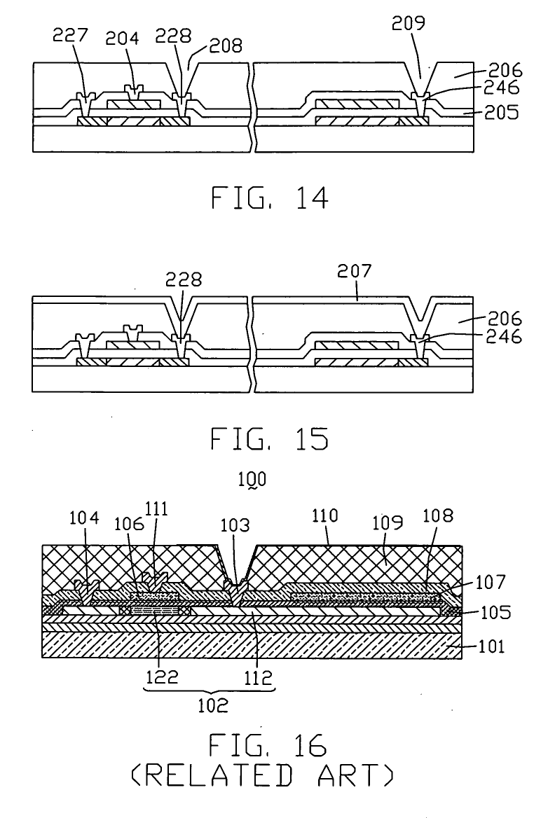

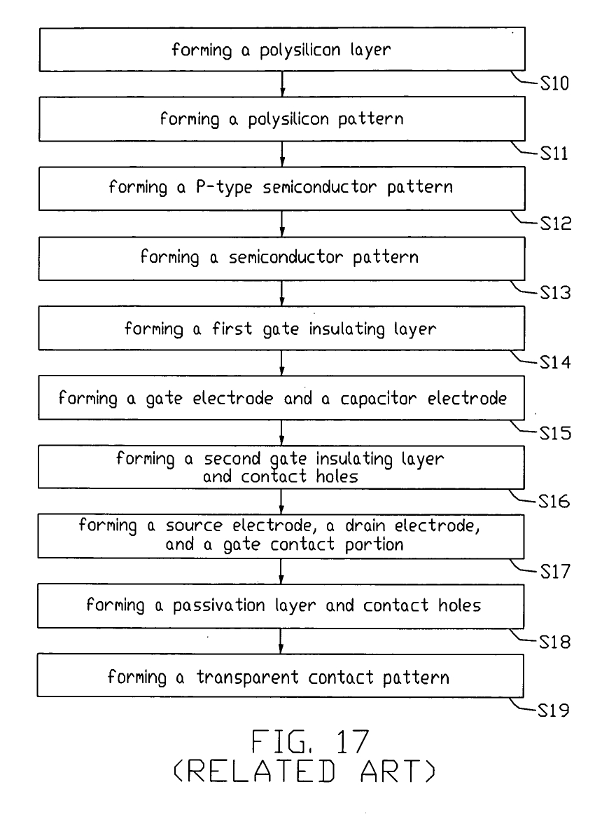

In step S24, the gate electrode 223 and the common capacitor electrode 245 are formed. Referring also to FIG. 10, a first metal layer and a second photo-resist layer are formed on the first gate insulating layer 203. A second photo-mask is provided to expose and develop the second photo-resist layer, so as to form a second photo-resist pattern. Then the gate electrode 223 and the capacitor electrode 245 are formed by etching the first metal layer. The second photo-resist pattern is removed.

In step S25, the semiconductor pattern 202 is formed. Referring also to FIG. 11, the gate electrode 223 and the capacitor electrode 245 are used as a mask. Quinquevalent ions are doped in the P-type semiconductor pattern 304. Then part of the P-type semiconductor pattern 304 shaded by the gate electrode 223 and the capacitor electrode 245 forms the lightly doped polysilicon pattern 213, and part of the P-type semiconductor pattern 304.not shaded by the gate electrode 223 and the capacitor electrode 245 forms the heavily doped polysilicon pattern 212. The heavily doped polysilicon pattern 212 and the lightly doped polysilicon pattern 213 cooperatively constitute the semiconductor pattern 202.

In step S26, the second gate insulating layer 205, the source contact hole, the drain contact hole, the gate contact hole, and the capacitor contact hole are formed. Referring also to FIG. 12, a second silicon oxide layer as the second gate insulating layer 205 and a third photo-resist layer are formed on the gate electrode 223, the common capacitor electrode 245, and the first gate insulating layer 203. A third photo-mask is provided to expose and develop the third photo-resist layer, so as to form a third photo-resist pattern. Then the source contact hole, the drain contact hole, the gate contact hole, and the capacitor contact hole are formed by etching the first and second gate insulating layers 203, 205. The third photo-resist pattern is removed.

In step S27, the source electrode 227, the drain electrode 228, the gate contact portioncontact portion 204, and the capacitor contact portioncontact portion 246 are formed. Referring also to FIG. 13, a second metal layer and a fourth photo-resist layer are formed on the second gate insulating layer 205. The second metal layer is connected to the heavily doped polysilicon pattern 212 via the source contact hole, the drain contact hole, and the capacitor contact hole, respectively. The second metal layer is connected to the gate electrode 223 via the gate contact hole. A fourth photo-mask is provided to expose and develop the fourth photo-resist layer, so as to form a fourth photo-resist pattern. Then the source electrode 227, the drain electrode 228, the gate contact portioncontact portion 204, and the capacitor contact portioncontact portion 246 are formed by etching the second metal layer. The fourth photo-resist pattern is removed.

In step S28, the passivation layer 206, the first contact hole 208, and the second contact hole 209 are formed. Referring also to FIG. 14, the passivation layer 206 and a fifth photo-resist layer are formed on the drain electrode 228, the source electrode 227, the gate contact portioncontact portion 204, the capacitor contact portioncontact portion 246, and the second gate insulating layer 205. A fifth photo-mask is provided to expose and develop the fifth photo-resist layer, so as to form a fifth photo-resist pattern. Then the first contact hole 208 and the second contact hole 209 are formed by etching the passivation layer 206. The fifth photo-resist pattern is removed.

In step S29, the transparent contact pattern 207 is formed. Referring also to FIG. 15, a transparent conducting layer and a sixth photo-resist layer are formed on the passivation layer 206. The transparent conducting layer is connected to the drain electrode 228 and the capacitor contact portioncontact portion 246 via the first and second contact holes 208, 209 in the passivation layer 206, respectively. A sixth photo-mask is provided to expose and develop the sixth photo-resist layer, so as to form a sixth photo-resist pattern. Then the transparent contact pattern 207 is formed by etching the transparent conducting layer. The sixth photo-resist pattern is removed.

The gate electrode 223 and the capacitor electrode 245 are used as a mask in the above method, and thereby obviating the need for a photo-mask. That is, the method for fabricating the TFT substrate 200 only needs a total of six photo-mask processes. The method is relatively simple and inexpensive.

It is to be understood, however, that even though numerous characteristics and advantages of preferred and exemplary embodiments have been set out in the foregoing description, together with details of the structures and functions of the embodiments, the disclosure is illustrative only; and that changes may be made in detail, especially in matters of shape, size, and arrangement of parts within the principles of the present invention to the full extent indicated by the broad general meaning of the terms in which the appended claims are expressed.

What is claimed is:

1. A thin film transistor substrate, comprising:
a base;
a semiconductor pattern formed on the base, the semiconductor pattern comprising a heavily doped polysilicon pattern and a lightly doped polysilicon pattern;
a first gate insulating layer formed on the semiconductor pattern; and
a gate electrode and a common capacitor electrode formed on the first gate insulating layer;
wherein the gate electrode and the common capacitor electrode correspond to the lightly doped polysilicon pattern.

2. The thin film transistor substrate of claim 1, further comprising a first capacitor, wherein the first capacitor comprises a first electrode, and the first electrode is part of the lightly doped polysilicon pattern corresponding to the common capacitor electrode.

3. The thin film transistor substrate of claim 2, further comprising a second gate insulating layer, wherein the second gate insulating layer is formed on the gate electrode, the common capacitor electrode, and the first gate insulating layer.

4. The thin film transistor substrate of claim 3, further comprising a drain electrode, a source electrode, a gate contact portioncontact portion, and a capacitor contact portioncontact portion, wherein the drain electrode, the source electrode, the gate contact portioncontact portion, and the capacitor contact portioncontact portion are formed on the second gate insulating layer.

5. The thin film transistor substrate of claim 4, wherein the capacitor contact portioncontact portion is connected to the first electrode via a capacitor contact holecontact hole in the first and second gate insulating layers.

6. The thin film transistor substrate of claim 5, wherein the drain electrode and the source electrode are connected to the semiconductor pattern via a drain contact holecontact hole and a source conducting hole in the first and second gate insulating layers respectively, and the gate contact portioncontact portion is connected to the gate electrode via a gate contact holecontact hole in the second gate insulating layer.

7. The thin film transistor substrate of claim 6, further comprising a passivation layer, wherein the passivation layer is formed on the drain electrode, the source electrode, the gate contact portioncontact portion, the capacitor contact portioncontact portion, and the second gate inslulating layer.

8. The thin film transistor substrate of claim 7, further comprising a transparent contact pattern, wherein the transparent contact pattern is formed on the passivation layer, the transparent contact pattern comprises a pixel electrode and a second electrode, the pixel electrode is connected to the drain electrode via a first contact holecontact hole in the passivation layer, and the second electrode is connected to the capacitor contact portioncontact portion via a second transparent contact pattern.

9. The thin film transistor substrate of claim 8, further comprising a second capacitor, wherein the second capacitor is connected parallel to the first capacitor, and the second electrode and the common capacitor electrode are two electrodes of the second capacitor.

10. The thin film transistor substrate of claim 9, further comprising a plurality of gate lines, wherein the gate electrode and the common capacitor electrode are connected to two adjacent gate lines, respectively.

11. A method for fabricating a thin film transistor substrate, the method comprising:
providing a base;
forming a polysilicon pattern on the base in a first photo-mask process;
forming a first gate insulating layer on the polysilicon pattern;
forming a gate electrode and a common capacitor electrode on the first gate insulating layer in a second photo-mask process; and
forming a heavily doped polysilicon pattern and a lightly doped polysilicon pattern by doping the polysilicon pattern using the gate electrode and the common capacitor electrode as a mask;
wherein the gate electrode and the common capacitor electrode correspond to the lightly doped polysilicon pattern.

12. The method of claim 11, further comprising: forming a second gate insulating layer on the gate electrode, the common capacitor electrode, and the first gate insulating layer; and forming a source contact holecontact hole, a drain contact holecontact hole, a gate contact holecontact hole, and a capacitor contact holecontact hole in a third photo-mask process.

13. The method of claim 12, further comprising: forming a source electrode, a drain electrode, a gate contact portioncontact portion, and a capacitor contact portioncontact portion on the second gate insulating layer in a fourth photo-mask process.

14. The method of claim 13, further comprising: forming a passivation layer on the source electrode, the drain electrode, the gate contact portioncontact portion, the capacitor contact portioncontact portion, and the second gate insulating layer; and forming a first contact hole and a second contact hole in the passivation layer in a fifth photo-mask process.

15. The method of claim 14, further comprising: forming a transparent contact pattern on the passivation layer in a fifth photo-mask process.

16. The method of claim 11, further comprising: forming a P-type semiconductor pattern by doping the polysilicon pattern, before forming the first gate insulating layer.
